(19) United States
(12) Patent Application Publication
(10) Pub. No.: US 2012/0223419 A1
(43) Pub. Date: Sep. 6, 2012

(54) METHOD FOR CONTROLLING THE DISTRIBUTION OF STRESSES IN A SEMICONDUCTOR-ON-INSULATOR TYPE STRUCTURE AND CORRESPONDING STRUCTURE

(75) Inventors: Sébastien Kerdiles, Saint-ismier (FR); Patrick Reynaud, Saint Martin D'heres (FR)

(73) Assignee: SOITEC, Bernin (FR)

(21) Appl. No.: 13/458,817

(22) Filed: Apr. 27, 2012

Related U.S. Application Data
(63) Continuation of application No. PCT/EP2010/064604, filed on Sep. 30, 2010.

(30) Foreign Application Priority Data
Oct. 30, 2009 (FR) 09 57662

(51) Int. Cl. H01L 29/06; H01L 21/30

(52) U.S. Cl. 257/637; 438/458; 257/E29.006; 257/E21.211

(57) ABSTRACT

A method for controlling the distribution of the stresses in a structure of the semiconductor-on-insulator type during its manufacturing, which includes a thin layer of semiconducting material on a supporting substrate and an insulating layer present on each of the front and rear faces of the supporting substrate, with the insulating layer on the front face forming at least one portion of a thick buried insulator (BOX) layer. The method includes the adhesive bonding of the thin layer onto the supporting substrate. Prior to this adhesive bonding, the insulating layer on the rear face of the supporting substrate is covered with a distinct material that is capable of withstanding deoxidation. The covering material, in combination with this insulating layer on the rear face of the supporting substrate, at least partly compensates for the stress exerted by the buried insulator (BOX) on the supporting substrate.

### CROSS-REFERENCE TO RELATED APPLICATIONS

This application is a continuation of International Application PCT/EP2010/064604 filed Sep. 30, 2010, the entire content of which is expressly incorporated herein by reference thereto.

### BACKGROUND

The invention relates to a method for controlling the distribution of stresses in a structure of the semiconductor-on-insulator type during its manufacturing. It also relates to such a structure, which may be used in the fields of microelectronics, optoelectronics, integrated photonics, etc.

With bonding by molecular adhesion, it is possible to make substrates of the SOI (Silicon On Insulator) type, by burying an insulating layer between a mechanical supporting substrate and an active semiconductor layer. Generally, SOI substrates include an active layer and a mechanical supporting substrate in single crystal silicon, while the insulator is often a silicon oxide.

Methods such as those respectively known under the brand of “Smart Cut™” or under the acronym of “BESOI” (“Bonded and Etched-Back Silicon on Insulator”) involve the molecular or adhesive bonding of two substrates, one being the receiver (i.e., the future mechanical supporting substrate) and the other one being the donor from which the active layer is extracted. In order to form the buried insulator, all or part of the insulator may be formed or deposited on either one of the two substrates prior to bonding.

Currently, the totality of the insulator is formed on the donor substrate, in particular if the final buried insulator is thin (<500 nm). In other cases, in particular if the buried insulator is thick (>2000 nm), the donor substrate may only bring a small portion of the future buried insulator (e.g., 200 nm), the remainder (e.g., 1800 nm) being provided by the supporting substrate.

The presence of a buried insulator leads to deformation of the finished SOI. Indeed, for example, in the case of buried Si oxide (100-1000 nm) between a support of thickness 400-800 μm and an active layer of Si with a thickness of 10-10,000 nm, the structure is not symmetrical and deforms because the oxide does not have the same heat expansion coefficient as silicon. It is again found that under a stress which relaxes in order to give a “deflection” to the substrate that a deformation to the finished SOT substrate is encountered. This deflection is all the greater since the insulator is thick.

A slight deformation of the thereby made wafers is tolerable by the users. On the other hand, beyond a certain deformation (amplitude<50 μm) depending on the fineness of the components made on the SOIs, focusing problems occur during photolithographic steps, or even to the utmost, problems are experienced when the wafers are handled by robots.

There is a need for SOI wafers with the desired buried insulator thickness to also avoid significant deformation. The manufacturing of an SOI with a thick buried insulator and with small deflection is therefore difficult and requires resorting to particular precautions and methods.

Up to now, in order to limit the stresses and therefore the deflection, a first solution to the problem consisted of manufacturing SOIs with a thick buried insulator by adhesively bonding a donor substrate that included a small portion of the oxide, to a receiver which included the major portion of the future buried oxide, or even the totality thereof. In order to avoid deformation of the finished SOI, the receiver not only included the oxide on the front face, but also on the rear face (which for example is the case with thermal oxidation). This rear face oxide should be preserved until the end of the SOI manufacturing method, which is a constraint since the different deoxidation steps (at least one deoxidation step that is conducted after the stabilization step, and possibly a second one after the thinning step) have only to be performed on the front face.

This kind of method is feasible but is costly and imposes the manufacturing of thick buried oxide SOIs by means of specific equipment (deoxidation exclusively on the front face, etc.). Moreover, SOIs with such an oxide on the rear face, delivered to the manufacturers of electronic components, also force the users to themselves perform deoxidation only on the front face. The deformation of an oxide structure on the rear face will be zero if the thick buried oxide SOI includes the same oxide thickness on the rear face of the receiver substrate.

If during the method for manufacturing the SOI or components on this SOI, the rear face oxide is partly removed, the deformation again appears with an amplitude depending on the difference in thickness between the buried oxide and that on the rear face. For example, an SOI with buried oxide (BOX) of thickness 1,000 nm is characterized by a deformation amplitude of about 85 μm, if no oxide is present in the rear face. This amplitude can be reduced to about 40 μm if 500 nm of oxide are left in the rear face. Thus, there remains a need for improved processes to combat these problems, and these are now provided by the present invention.

### SUMMARY OF THE INVENTION

The present invention therefore aims to solve this problem by proposing a method for controlling the distribution of the stresses in a structure of the semiconductor-on-insulator type during its manufacturing, which is simple and easy to apply, and with which the deformation of the obtained structure may be “managed” on demand.

Thus, this method for controlling the distribution of the stresses of distribution in a structure of the semiconductor-on-insulator type during its manufacturing, which includes a thin layer of semiconducting material on a supporting substrate, an insulating layer being present on each of the front and rear faces of the supporting substrate, the front insulating face forming at least one portion of a thick buried insulator, a manufacturing method according to which it is proceeded with adhesive bonding of said thin layer on said supporting substrate, is characterized by the fact that prior to bonding, it is proceeded with covering of said insulating layer, on the rear face of said supporting substrate with a distinct material withstanding deoxidation, a material which, in combination with this insulating layer on the rear face of the supporting substrate, at least partly compensates for the stress exerted by the buried insulator on the supporting substrate.

In this way, not only the insulating layer on the rear face of the supporting substrate at least partly compensates for the stress exerted by the buried insulator on the supporting substrate, but is also protected by the material withstanding deoxidation.

Moreover, the invention relates to a structure of the semiconductor-on-insulator type, which includes a thin layer of semiconducting material on a supporting substrate, an insulating layer being present on each of the front and rear faces of the supporting substrate, the layer on the front face forming at least one portion of a thick buried insulator, with the structure including a layer for covering the insulating layer on the rear face of the supporting substrate consisting of a distinct material, capable of withstanding deoxidation, a material which, in combination with this insulating layer on the rear face of the supporting substrate, at least partly compensates for the stress exerted by the buried insulator on the supporting substrate.

Advantageously, the difference in thickness between the insulator layers on the front face and on the rear face of the supporting substrate is less than or equal to 200 nanometers.

### BRIEF DESCRIPTION OF THE DRAWINGS

Other features and advantages of the present invention will become apparent upon reading the description which follows of certain embodiments. This description will be made with reference to the appended drawings wherein:

FIGS. 1-3 are sectional views of a structure according to the invention illustrated in three different stress conditions, respectively;

FIG. 4 is a sectional view of a further alternative of the structure; and

FIGS. 5A-5J are simplified views of the steps with which the structure of FIG. 1 may be obtained.

### DETAILED DESCRIPTION OF THE INVENTION

In the present application, the terms and expressions hereafter will have the associated definitions:

A thick buried insulator: a buried insulator with a thickness of at least 500 nm, or even of at least 800 nm;

Material withstanding deoxidation: a material for which the etching rate by hydrofluoric acid (HF, at a concentration comprised between 0.5% and 50%, preferentially from 10 to 20%, and at a temperature generally comprised between 20 and 25° C.) is at least 10 times less than that of silicon oxide. This will also be referred to as a deoxidation resistant material.

Advantageous and non-limiting features of these processes include:

the insulating layer notably includes an oxide;

the thick buried insulator consists of an insulator layer added onto the thin layer and/or of an insulator layer added on the supporting substrate;

the thick buried insulator and the insulating layer on the rear face of the supporting substrate exert a same stress level on this substrate;

the thick buried insulator and the insulating layer on the rear face of the supporting substrate exert different stress levels on this substrate;

the material withstanding deoxidation is proceeded not only with covering of the rear face of the supporting substrate, but also with covering its other faces, in order to encapsulate entirely the support substrate;

the layer of material withstanding deoxidation on the front face of supporting substrate can be removed;

the material withstanding deoxidation is preferably selected from polycrystalline silicon, notably doped with boron or phosphorus for example, amorphous silicon, possibly doped or silicon nitrides;

the material withstanding deoxidation is most preferably a polycrystalline silicon and, prior to covering the insulating layer on the rear face of the supporting substrate, it is proceeded with the removal of an intermediate insulating layer on the front face of the supporting substrate;

the intermediate insulating layer is a layer obtained during the formation of the insulating layer on the rear face of the supporting substrate;

the insulating layer on the front face of the supporting substrate is formed by thermal oxidation, or by depositing oxide on the polycrystalline silicon and/or on a donor substrate which integrates the thin layer;

the supporting substrate is subject to a treatment capable of imparting high resistivity to it, i.e., to at least greater than 5000 Ω·cm, preferentially greater than 1,0000 Ω·cm.

According to a preferred embodiment, the invention relates to improvements in a method for manufacturing a SOI structure that includes a thin layer of semiconducting material on a supporting substrate, and an insulating layer being present on each of the front and rear faces of the supporting substrate, wherein the insulating layer on the front face forms at least a portion or all of a thick buried insulator (BOX) layer in the SOI structure. In this method, the improvement comprises controlling stress distribution on the supporting substrate by covering the insulating layer on the rear face of the supporting substrate with a distinct deoxidation resistant material with that material, in combination with the insulating layer on the rear face of the supporting substrate, at least partly compensating for stresses exerted by the BOX layer on the supporting substrate. In particular, the covering of the insulating layer on the rear face of the supporting substrate is conducted prior to bonding of the thin layer to the supporting substrate.

The thin layer is typically transferred to the support substrate by molecular bonding of a donor wafer to the supporting substrate and the removal of the main part of the donor wafer to leave the thin layer bonded to the supporting substrate. According to the SmartCut™ process, a zone of weakness which defines the thin layer is provided in a donor substrate prior to molecular bonding with the supporting substrate, and then the zone of weakness is fractured by the application of heat or mechanical forces to transfer the thin layer to the supporting substrate.

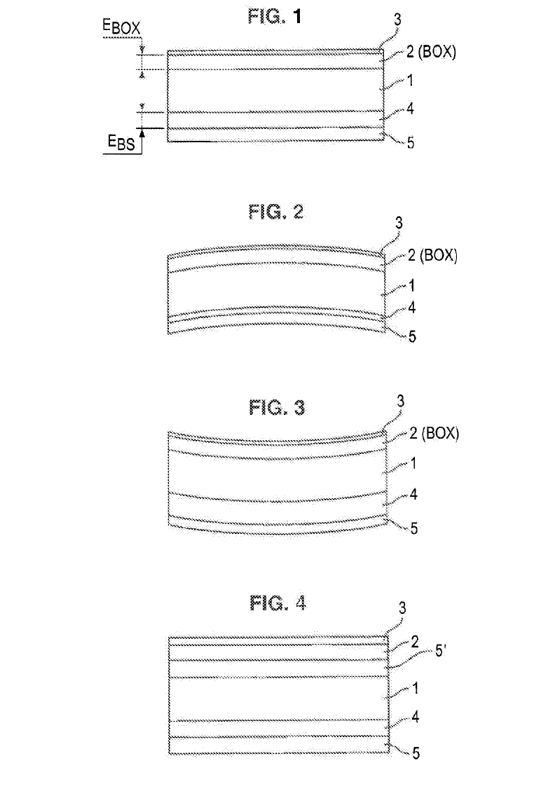

A structure according to the invention is visible in FIG. 1. On a mechanical supporting substrate 1, the SOI comprises a buried insulator 2 of thickness EBOX and an active layer 3. Under the supporting substrate, an encapsulated insulator 4 of thickness EBS is located between this support and a layer 5 which protects the 25 insulator 4 from etching or deoxidation. The deformation of the thereby formed SOI is managed by selecting the thickness and the stress of the layers of insulators 2 and 4. In the case when the stress is identical, the deformation is closer to zero if EBS=EBOX (FIG. 1).

In order to anticipate deformation occurring subsequently in the method for manufacturing components on the SOI, the operator may require an SOI with non-zero deformation, i.e. positive deflection (EBS<EBOX, when the SOI is convex, as shown in FIG. 2) or negative deflection (EBS>EBOX, when the SOI is concave as shown in FIG. 3).

For example, the BOX layer and the insulating layer on the rear face of the supporting substrate will exert the same amount of stress on the supporting substrate when they have the same thickness and are made of the same material. Alternatively, the BOX layer and the insulating layer on the rear face of the supporting substrate can exert different stress levels on the supporting substrate when they have different thicknesses or are made of different materials.

In the case when the insulator layers 2 and 4 do not have the same stress level, one may be led to taking this stress into account in order to adjust the thickness of the layer 4 in order to attain the desired deformation. Also, if the layer 5 encapsulated in the insulator on the rear face contributes to the deformation of the SOI, the thickness of the layers 4 and 5 may be corrected.

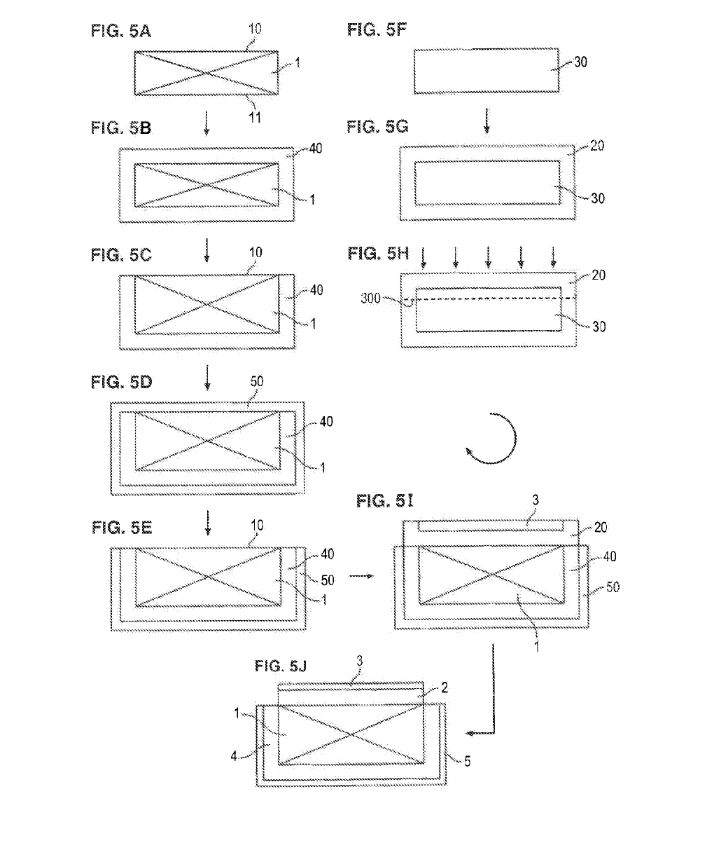

The different steps of the method with which the structure illustrated in FIG. 1 may be obtained, are illustrated in FIGS. 5A-5J. Here, this is a structure, for which both the supporting and donor substrates are in silicon with a silicon oxide insulator. The supporting substrate in silicon 1 is illustrated in FIG. 5A and its front and rear faces are identified by 10 and 11.

A step for forming an insulator 40 is illustrated in FIG. 5B, which is typically formed by thermal oxidation of the supporting substrate, or further by depositing a thin layer, notably by the Low chemical Pressure Vapor Deposition (LPCVD) technique. The oxide formed in this step on the rear face of the supporting substrate 1 has a thickness equal to the future buried oxide which will be formed under the future active layer.

As illustrated in FIG. 5C, it is proceeded 30 with deoxidation only on the front face 10 of the supporting substrate 1. As shown in FIG. 5D, a deposition of an encapsulation layer 50 is then carried out on all the surfaces of the supporting substrate, for example by the LPCVD technique, and it is then proceeded with removing this layer on the front face of the supporting substrate, as shown in FIG. 5E. The material used for the encapsulation layer 50 may for example be a layer of polycrystalline silicon, amorphous silicon, or further a layer of silicon nitride.

A donor substrate 30 is illustrated in FIG. 5F. As shown in FIG. 5G, it is proceeded with thermal oxidation so as to form an oxide 20 with a thickness identical to the buried oxide under the supporting substrate 1, so as to obtain a finished structure with quasi-zero deformation. A step for ion implantation in the donor substrate in order to form an embrittlement area 300 or zone of weakness is illustrated in FIG. 5H. It is then proceeded with turning-over of the donor substrate 30 and with bonding by molecular adhesion onto the supporting substrate 1.

It is then proceeded with fracture of the donor substrate 30 along the embrittlement area 300 in order to transfer it onto the supporting substrate 1, the semiconducting material layer 3 and its insulator 20. Finally, it is proceeded with steps for finishing the structure by notably applying deoxidation by immersion in one or several pans of hydrofluoric acid (HF), in order to obtain the structure illustrated in FIG. 5I.

During these steps for finishing the SOI (steps after transferring the thin layer), one or more cleaning operations comprising an HF bath are used for removing the oxide on the front face of the supporting substrate. During these immersions, its rear face is also exposed to etching by HF. Because of the presence of the encapsulation layer, the latter is not or practically not etched. Thus, the etching rate by HF of a nitride layer obtained by LPCVD is about 30 times slower than that of a thermal oxide. The etching rate of an amorphous or polycrystalline silicon layer is quasi-zero under the same conditions. From a selectivity at least equal to 10, it may be considered, as mentioned above, that the material withstands deoxidation and is a deoxidation resistant material according to the invention.

An alternative of the structure according to the invention is illustrated in FIG. 4, wherein the supporting substrate has high resistivity. It includes a polycrystalline silicon layer 5′ under the buried oxide 2, and has zero deformation, in spite of a buried oxide with a thickness of 1,000 nm, this by an oxide layer 4 on the rear face of the supporting substrate 1, which is encapsulated under a layer of polycrystalline silicon 5.

The manufacturing technique for this structure is substantially the same as the one indicated above, but the supporting substrate was subject beforehand to heat treatment making it highly resistive (resistivity greater than 500 Ω·cm, and preferentially greater than 1,000 Ω·cm). Moreover, it undergoes thermal oxidation in order to generate an oxide with a thickness of 800 nm on all its faces.

After deoxidation of its front face, it is 30 proceeded with the LPCVD deposition of polycrystalline silicon on all its faces, over a thickness of one micrometer. Thermal oxidation of a donor substrate is thereby achieved so as to form an oxide layer of 800 nm, i.e., having a thickness identical with that of the oxide already formed under the supporting substrate, in order to obtain a finished structure with quasi-zero deformation.

The thereby obtained structure benefits from a buried oxide 4 on the rear face which ensures minimum deformation, it compensates for the stresses which would have been caused by the buried oxide 2 under the active layer 3. The polycrystalline silicon 5 and 5′ which is deposited is practically pure (residual doping level of less than 1×10¹⁵ atoms per cm²), so as to provide under the buried oxide 2 a layer 5′ which further improves the electric performances of the structure in the radiofrequency range.

Further, with the polycrystalline silicon layer 5 on the rear face of the supporting substrate, it is possible to protect the oxide layer 4 from etching during the finishing of the structure and to continue to protect it until the end of the method for manufacturing components of the structure.

In another exemplary embodiment not shown in the figures, it is proceeded with thermal oxidation of a supporting substrate over a thickness of 1,800 nm. It is then proceeded with deposition of amorphous silicon (1 nm), on all the faces of the supporting substrate, and then with removal of this amorphous silicon on its front face. Thermal oxidation of a donor substrate on a thickness of 200 nm is applied. Finally, it is proceeded with the making of an SOI by the aforementioned Smart-Cut™ technique, by means of both of these substrates.

It is characterized by a buried oxide with a total thickness of 2 μm and an oxide on the rear face of 1.8 nm encapsulated by amorphous silicon. The thereby obtained SOI typically has a deflection of 20 nm (slightly convex). This deformation would be on the order of 200 nm if the oxide was not encapsulated on the rear face of the supporting substrate.

What is claimed is:

1. In a method for manufacturing a semiconductor-on-insulator (SOI) structure that includes a thin layer of semiconducting material on a supporting substrate, an insulating layer being present on each of the front and rear faces of the supporting substrate, the insulating layer on the front face forming at least a portion or all of a thick buried insulator (BOX) layer in the SOI structure, the improvement which comprises:
controlling stress distribution on the supporting substrate by covering the insulating layer on the rear face of the supporting substrate with a distinct deoxidation resistant material with that material, in combination with the insulating layer on the rear face of the supporting substrate, at least partly compensating for stresses exerted by the BOX layer on the supporting substrate;
wherein the covering of the insulating layer on the rear face of the supporting substrate being conducted prior to bonding of the thin layer to the supporting substrate.

2. The method according to claim 1, wherein the thin layer is transferred to the support substrate by molecular bonding of a donor wafer to the supporting substrate and the removal of the main part of the donor wafer to leave the thin layer bonded to the supporting substrate.

3. The method according to claim 1, wherein the insulating layer comprises an oxide.

4. The method according to claim 1, wherein the BOX layer consists partly of an insulator layer present on thin layer and partly of an insulator layer present on the supporting substrate wherein the insulator layers are bonded to each other to form the BOX layer.

5. The method according to claim 1, wherein the BOX layer consists of an insulator layer present only on the supporting substrate.

6. The method according to claim 1, wherein the BOX layer and the insulating layer on the rear face of the supporting substrate exert the same amount of stress on the supporting substrate.

7. The method of claim 6, wherein the BOX layer and the insulating layer on the rear face of the supporting substrate have the same thickness and are made of the same material.

8. The method according to claim 1, wherein the BOX layer and the insulating layer on the rear face of the supporting substrate exert different stress levels on the supporting substrate.

9. The method of claim 6, wherein the BOX layer and the insulating layer on the rear face of the supporting substrate have different thicknesses or are made of different materials.

10. The method according to claim 1, which further comprises applying the deoxidation resistant material to encapsulate all faces of the supporting substrate and subsequently removing the layer of insulating material on the front face of the supporting substrate prior to bonding.

11. The method according to claim 1, wherein the deoxidation resistant material is polycrystalline silicon, doped polycrystalline silicon, amorphous silicon, doped amorphous silicon or silicon nitride.

12. The method according to claim 11, wherein the front face of the supporting substrate has an intermediate insulating layer, the deoxidation resistant material is polycrystalline silicon, and the deoxidation resistant material is applied to cover the entire supporting substrate after removal of the intermediate insulating layer from the front face of the supporting substrate.

13. The method according to claim 12, wherein the intermediate insulating layer on the front face of the supporting substrate is obtained during the formation of the insulating layer on the rear face of the supporting substrate.

14. The method according to claim 12, wherein the intermediate insulating layer on the front face of the supporting substrate is formed by thermal oxidation, or by deposition of an oxide on the polycrystalline silicon and/or on a donor substrate which provides the thin layer.

15. The method according to claim 1, which further comprises subjecting the supporting substrate to a treatment that imparts a high resistivity of greater than 5000 Ω·cm to the supporting substrate.

16. A semiconductor-on insulator (SOI) structure, which includes a thin layer of semiconducting material on a supporting substrate, an insulating layer on each of the front and rear faces of the supporting substrate, the layer on the front face forming at least one portion of a thick buried insulator (BOX) layer, wherein the structure includes a layer for covering the insulating layer on the rear face of the supporting substrate, the layer consisting of a distinct deoxidation resistant material, wherein that material, in combination with the insulating layer on the rear face of the supporting substrate, at least partly compensates for stresses exerted by the BOX layer on the supporting substrate.

17. The structure according to claim 16, wherein the layers of insulator on the front face and on the rear face of the supporting substrate have thicknesses that differ by less than or equal to 200 nanometers.

18. The structure according to claim 16, wherein the supporting substrate has a high resistivity that is greater than 5000 Ω·cm.
